(19) United States
(12) Patent Application Publication
(10) Pub. No.: US 2016/0305986 A1
(43) Pub. Date: Oct. 20, 2016

(54) Device for Detecting and Measuring the Current and Voltage of Electric Circuits in a Building

(71) Applicant: Timothy Shane McClure, Desert Hot Springs, CA (US)

(72) Inventor: Timothy Shane McClure, Desert Hot Springs, CA (US)

(21) Appl. No.: 15/193,017

(22) Filed: Jun. 25, 2016

Related U.S. Application Data
(63) Continuation-in-part of application No. 14/257,068, filed on Apr. 21, 2014.

(51) Int. Cl. G01R 19/15

(52) U.S. Cl. CPC G01R 19/15

(57) ABSTRACT

Disclosed is a device for measuring the current and voltage of electric circuits in a building. The device has a speaker that is detachable from the housing of the device, a receiver that can use a rechargeable battery, a digital voltmeter that can accurately measure up to 220 volts, and a light fixture adapter that can detect current through a light fixture.

### CROSS REFERENCE TO RELATED APPLICATIONS

The present invention is a continuation-in-part (CIP) of U.S. patent application Ser. No. 14/257,068, filed 21 Apr. 2014, entitled “Electric Circuit Isolator Tester”, by Timothy S. McClure.

### BACKGROUND OF THE INVENTION

a. Field of the Invention

The present invention generally pertains to measuring and testing electric circuits in a building.

b. Description of the Background

For safety reasons, electricians should always turn off electric current to any electrical outlet they will be examining before beginning to work on that outlet. For residential or commercial buildings, turning off electric current often involves shutting off electric current to the entire property.

To ensure that electric current is not flowing into an outlet under examination, a device is often connected to the outlet that visually indicates a voltage when electric current is flowing and zero voltage when electric current is not flowing. In order to see the testing machine's visual indication, an electrician must either spend time walking back and forth between the outlet under examination and a set of circuit breakers until he has isolated and turned off the correct circuit breaker(s) for the given outlet, or engage a second person to do nothing but watch the testing machine and call to the electrician when the visual indication is zero. Both of these methods are inefficient and would be substantially improved by using a device that emits an audible signal when electric current is flowing instead of a visual signal.

U.S. Pat. No. 6,731,217 (Warner) discloses an electrical circuit tester with prongs that can fit into an electrical outlet, as well as a set of lights that indicate the status of an electrical outlet and a speaker that creates an audible tone when the prongs engage the electrical outlet. However, Warner's speaker is not detachable from the housing of the tester, which would allow the tester to be used at a greater distance from the operator.

U.S. Patent Publication 20070001683 (Krigel) discloses the use of a wireless transmitter and receiver capable of transmitting and receiving test result messages to wireless headphones. However, Krigel's transmitter is specifically designed to transmit findings of short circuits within wiring harnesses as used in an aircraft and not designed for use in studying the circuits of a building. Krigel's receiver does not disclose a rechargeable battery. Krigel also does not disclose the inclusion of a digital voltmeter that accurately measures voltage of up to 220 volts or the inclusion of a light fixture adapter that can detect current through a light fixture.

It would therefore be advantageous to have a circuit tester for use in a building whose speaker is detachable from the housing of the tester, whose receiver can use a rechargeable battery, that includes a digital voltmeter that can accurately measure up to 220 volts, and includes a light fixture adapter that can detect current through a light fixture.

### SUMMARY OF THE INVENTION

The present invention overcomes the disadvantages and limitations of the prior art by providing a device that measures the current and voltage of electric circuits in a building. The device has a speaker that is detachable from the housing of the device, a receiver that can use a rechargeable battery, a digital voltmeter that can accurately measure up to 220 volts, and a light fixture adapter that can detect current through a light fixture.

The present invention thus comprises: a device for detecting and measuring the current through and the voltage across an electric circuit in a building, comprising: a pronged plug that plugs into an electrical outlet; a circuit board that contains electrical components of the device; a computer chip, connected to the circuit board, that checks the polarity of an electric circuit and measures the voltage across the electric circuit, as detected by the pronged plug; a sound device that connects to the circuit board and makes an audible sound when current flows through it; a set of diodes that connects to the circuit board and allows current to flow between the pronged plug and the sound device; a detachable speaker that amplifies the sound created by the sound device and can be used at a greater distance from a user than a non-detachable speaker; a radio transmitter that transmits the sound created by the sound device a longer distance than can be transmitted by the sound device alone; a radio receiver with a rechargeable battery that receives the sound transmitted by the radio transmitter; a battery charger to recharge said rechargeable battery; and, a digital voltmeter that can accurately measure up to 115 volts.

The present invention may further comprise an adapter that connects to the pronged plug and allows accurate measurement of up to 220 volts by the digital voltmeter, as well as a light fixture adapter that connects to the pronged plug and detects the current through the device when the device is connected to a light fixture under test.

The advantages of the present invention are increased safety to a user, the capability of using a radio signal to cue a user whether or not current is flowing in a circuit, the digital voltmeter that can measure up to 220 volts, and the light fixture adapter.

### BRIEF DESCRIPTION OF THE DRAWINGS

In the drawings,

FIG. 1 is an illustration of one embodiment of the external case of the present invention.

### DETAILED DESCRIPTION OF THE INVENTION

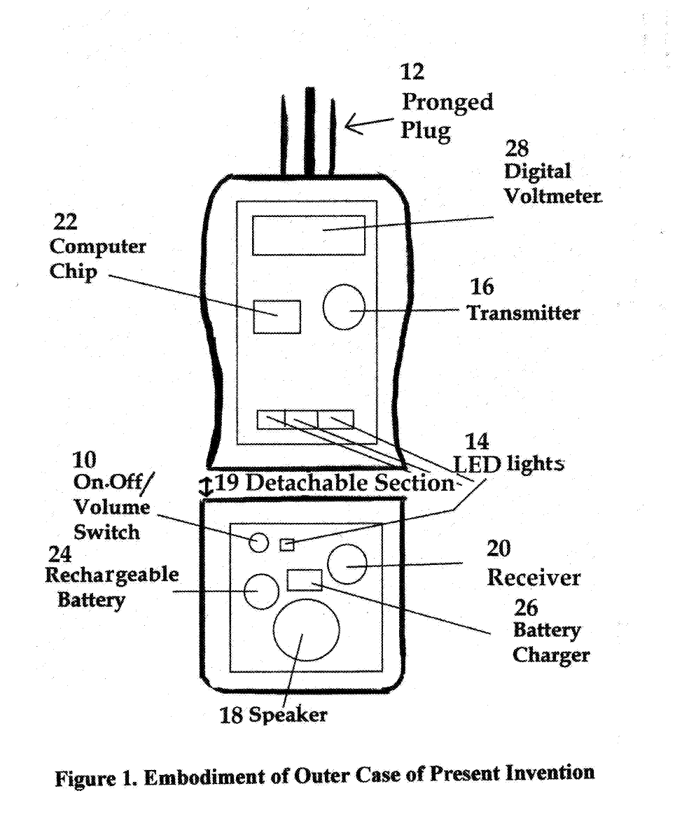

FIG. 1 illustrates a top view of one embodiment of the external case of the present invention. The embodiment may contain an on-off/volume switch 10, a pronged plug 12 that can be plugged into an electrical outlet, a set of LED lights 14, a radio transmitter 16, a speaker 18, a detachable section 19, a radio receiver 20, a computer chip 22, a rechargeable battery 24, a battery charger 26 and a digital voltmeter 28.

In one use of the present invention, a user may carry the present invention to an electrical outlet to be tested, connect the pronged plug 12 to an electrical outlet and turn on the on-off volume switch 10, which activates the LED lights 14. If electrical current is detected by the pronged plug 12, the speaker 18 may emit an audible sound. The user may then go a short distance away from the electrical outlet without carrying the present invention and examine a set of circuit breakers. The user may turn off circuit breakers one at a time until the speaker 18 no longer emits an audible sound, thus indicating that the electrical outlet now has no current flowing through it and can thus safely be examined. In another use of the present invention, a user may connect a wire clip adapter to the present invention and to a set of bare electrical wires and use the same process to ensure that the set of bare electrical wires now has no current flowing through it and can thus safely be examined.

Common embodiments of the present invention may include a circuit board inside the external case shown in FIG. 1. This circuit board may be connected to the computer chip 22 that checks the polarity of an electric circuit and measures the voltage across the electric circuit, as detected by the pronged plug 12. The circuit board may also contain a sound device that makes an audible sound when current flows through a set of diodes on the circuit board 22. A separate connection may connect the sound device with the speaker 18 and allow sound created by the sound device to be amplified by the speaker 18.

When the pronged plug 12 is connected to electrical power, the circuit board may also receive electrical power. Current may flow through a diode and fusible link before reaching the sound device and then the speaker 18 in a manner that causes an audible sound through the speaker 18 as long as current is flowing. When electrical power is removed, current may stop flowing and the sound device may no longer emit an audible sound, thus indicating that the electrical outlet now has no current flowing through it and can thus safely be examined.

If a dangerous amount of current unexpectedly flows through the pronged plug 12 or through a wire clip adapter connected to the present invention as a result of faulty wiring, a fusible link on the circuit board 22 may quickly melt and permanently become open. The current thus stops flowing, preventing the sound device from emitting an audible sound. This both adds an element of safety when testing an electrical outlet by preventing damaging levels of electric current that could shock or injure a user from flowing through the present invention and gives notice to a user of a change in current flow.

In optimum embodiments of the present invention, the part of the external case containing the speaker 18 may be part of a detachable section 19, allowing the present invention to be used at a greater distance from a user than a non-detachable speaker can be used. Sound transmitted by the radio transmitter 16 may be received by the radio receiver 20 and output to the speaker 18. The detachable section 19 may also contain the radio receiver 20 that has the rechargeable battery 24. The rechargeable battery 24 may be recharged with the battery charger 26, powered by the computer chip 22, when the on-off/volume switch 10 is off and the detachable section 19 is reconnected to the rest of the external case. The LED lights 14 may light up to indicate that the battery is fully charged, a feature also powered by the computer chip 22.

In some embodiments, the sound emitted by the speaker 18 may be detected through a headset worn by a user. The sound created by the flowing current is thus heard by a user but does not bother other people in the vicinity of the present invention.

Other embodiments of the present invention may include an adapter that connects to the pronged plug 12 and extends the maximum range of the digital voltmeter 28 from the 110-115 volts common in many buildings to 220 volts. Further embodiments of the present invention may include the capability to test light fixtures by using a light fixture adapter that connects to the pronged plug 12 and detects current flow by lighting up when current is flowing through a light fixture under test.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

1. A device for detecting and measuring the current through and the voltage across an electric circuit in a building, comprising:
a pronged plug that plugs into an electrical outlet;
a circuit board that contains electrical components of said device;
a computer chip, connected to said circuit board, that checks the polarity of an electric circuit and measures the voltage across said electric circuit, as detected by said pronged plug;
a sound device that connects to said circuit board and makes an audible sound when current flows through it;
a set of diodes that connects to said circuit board and allows current to flow between said pronged plug and said sound device;
a detachable speaker that amplifies the sound created by said sound device and can be used at a greater distance from a user than a non-detachable speaker;
a radio transmitter that transmits the sound created by said sound device a longer distance than can be transmitted by said sound device alone;
a radio receiver with a rechargeable battery that receives the sound transmitted by said radio transmitter;
a battery charger to recharge said rechargeable battery; and,
a digital voltmeter that can accurately measure up to 115 volts.

2. The device of claim 1, further comprising an adapter that connects to said pronged plug and allows accurate measurement of up to 220 volts by said digital voltmeter.

3. The device of claim 1, further comprising a light fixture adapter that connects to said pronged plug and detects the current through said device when said device is connected to a light fixture under test.
